(19) United States
(12) Patent Application Publication
(10) Pub. No.: US 2026/0123504 A1
(43) Pub. Date: Apr. 30, 2026

(54) THIN FILM RESISTORS

(71) Applicant: Texas Instruments Incorporated, Dallas, TX (US)

(72) Inventors: Jonas Hoehenberger, Kissing (DE); Michael Enzelberger-Heim, Muenchen (DE)

(21) Appl. No.: 18/929,593

(22) Filed: Oct. 28, 2024

(51) Int. Cl. H01L 23/00; H01L 21/768; H01L 23/522

(52) U.S. Cl. CPC H10W 72/30; H10W 20/056; H10W 20/081; H10W 20/42; H10W 20/498

(57) ABSTRACT

In described examples, a device includes a first and second thin film conductive regions, a thin film dielectric region, and first, second, third, and fourth vias. A first surface of the thin film dielectric region is coupled to a first surface of the first thin film conductive region, and a second surface of the thin film dielectric region is coupled to a first surface of the second thin film conductive region. The first via is coupled to a first end of the first thin film conductive region. The second via is coupled to a second end of the first thin film conductive region. The third via is coupled to a first end of the second thin film conductive region. The fourth via is coupled to a second end of the second thin film conductive region.

### TECHNICAL FIELD

This application relates generally to semiconductor device resistors, and in particular, to high precision thin film resistors fabricated as part of a semiconductor device.

### BACKGROUND

Fabrication of components within an integrated circuit (IC) typically considers and balances tradeoffs among various factors, including any one or more of critical dimension (CD) target, mask precision, layer thickness, conductive path resistance, and proximity effect. These factors can be further complicated by the various types of, and types of materials used to fabricate, components included in an IC. Such concerns can be magnified with respect to components used for highly sensitive applications, such as amplifiers for sensors included in industrial, automotive safety, or control (or other) systems.

### SUMMARY

In described examples, a device includes a first and second thin film conductive regions, a thin film dielectric region, and first, second, third, and fourth vias. A first surface of the thin film dielectric region is coupled to a first surface of the first thin film conductive region, and a second surface of the thin film dielectric region is coupled to a first surface of the second thin film conductive region. The first via is coupled to a first end of the first thin film conductive region. The second via is coupled to a second end of the first thin film conductive region. The third via is coupled to a first end of the second thin film conductive region. The fourth via is coupled to a second end of the second thin film conductive region.

### BRIEF DESCRIPTION OF THE DRAWINGS

FIG. 1 is a perspective view of a first example thin film resistor device.

FIG. 2A is a first perspective view of a second example thin film resistor device.

FIG. 2B is a second perspective view of the thin film resistor device of FIG. 2A.

FIGS. 3 through 10 are partial cross-sectional views representing successive example fabrication stages and resultant structures of the thin film resistor device of FIG. 1.

FIG. 11A is a top-down view representing an example first fabrication stage and resultant structures of the thin film resistor device of FIGS. 2A and 2B.

FIG. 11B is a partial cross-sectional view taken across a first line in FIG. 11A.

FIG. 11C is a partial cross-sectional view taken across a second line in FIG. 11A.

FIG. 12 is a partial cross-sectional view representing an example second fabrication stage and resultant structures of the thin film resistor device of FIGS. 2A and 2B.

FIG. 13 is a partial cross-sectional view representing an example third fabrication stage and resultant structures of the thin film resistor device of FIGS. 2A and 2B.

FIG. 14 is a partial cross-sectional view representing an example fourth fabrication stage and resultant structures of the thin film resistor device of FIGS. 2A and 2B.

FIG. 15A is a top-down view representing an example fifth fabrication stage and resultant structures of the thin film resistor device of FIGS. 2A and 2B.

FIG. 15B is a partial cross-sectional view taken across a first line in FIG. 15A.

FIG. 15C is a partial cross-sectional view taken across a second line in FIG. 15A.

FIG. 16 is a partial cross-sectional view representing an example sixth fabrication stage and resultant structures of the thin film resistor device 200 of FIGS. 2A and 2B.

FIG. 17 is a partial cross-sectional view representing an example seventh fabrication stage and resultant structures of the thin film resistor device of FIGS. 2A and 2B.

FIG. 18A is a top-down view representing an example eighth fabrication stage and resultant structures of the thin film resistor device of FIGS. 2A and 2B.

FIG. 18B is a partial cross-sectional view taken across a first line in FIG. 18A.

FIG. 18C is a partial cross-sectional view taken across a second line in FIG. 18A.

FIG. 19 is a partial cross-sectional view of the thin film resistor device of FIGS. 2A and 2B.

FIG. 20 is a table describing some example benefits of the thin film resistor device of FIGS. 2A and 2B, fabricated as described with respect to FIGS. 11A through 18C.

FIG. 21 is a flow diagram of a process for fabricating the thin film resistor device of FIG. 1.

FIG. 22 is a flow diagram of a process for fabricating the thin film resistor device of FIGS. 2A and 2B.

FIG. 23 is a partial cross-sectional view 2300 representing a modification of the thin film resistor device 100 of FIG. 1 to form a capacitor 2302.

FIG. 24 is a partial cross-sectional view 2400 representing a modification of the thin film resistor device 200 of FIG. 2 to form a capacitor 2302.

### DETAILED DESCRIPTION

Some amplifiers, such as highly accurate amplifiers used in automotive, industrial, and control applications, such as for sensors, use resistors that are closely matched to each other, and fabricated to accurately represent design specifications. A pair of resistors can be fabricated from a stacked arrangement formed (from bottom to top) from a first thin film conductive layer, a first thin film dielectric layer, a second thin film conductive layer, and a second thin film dielectric layer. Vias are electrically connected to the first thin film conductive layer, for example at opposing distal ends thereof, to form the first resistor. Vias are electrically connected to the second thin film conductive layer, again for example at opposing distal ends thereof, to form the second resistor.

Alternatively, a pair of stacked arrangements (alternating thin film conductive and dielectric layers as described above) can be diagonally connected to provide a closely matched pair of resistors. Here, diagonal connection refers to a first thin film conductive layer of a first stack electrically connected to a second thin film conductive layer of a second stack, and a second thin film conductive layer of the first stack electrically connected to the first thin film conductive layer of the second stack.

Herein, the same reference numbers or other reference designators are used in the drawings to designate features that are related structurally and/or functionally.

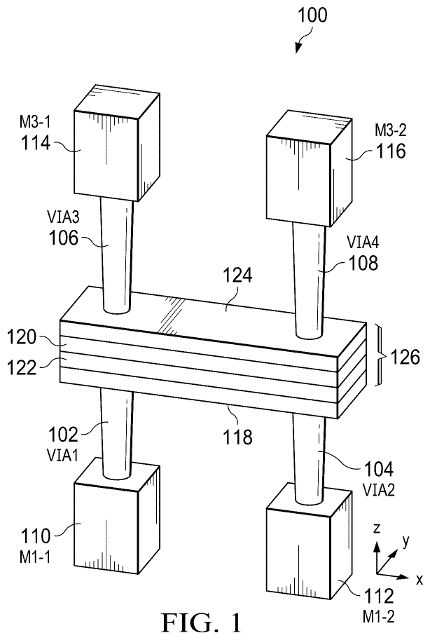

FIG. 1 is a perspective view of a first example thin film resistor (TFR) device 100. In some examples, the TFR device 100 is included in an IC device that includes a semiconductor substrate and various layers. The layers are deposited relative to one another or on a surface of the substrate, and include, for example, metal layers and dielectric layers. The substrate surface, and certain of the metal layers and dielectric layers included in the IC device, are described with respect to FIGS. 1 and 3 through 10. Metal layers are referenced with ascending numbers corresponding to ascending distance from the substrate surface. For example, M1 (a metal-1 layer) is closer to the substrate than M2, which is closer than M3, etc. Dimensions x, y, and z, and corresponding arrows in the perspective drawing that indicate these dimensions, are described below with reference to described components of the TFR device 100.

The TFR device 100 includes a first via (via1) 102, a second via (via2) 104, a third via (via3) 106, a fourth via (via4) 108, a first metal line (M1-1) 110 in an M1 layer, a second metal line (M1-2) 112 in the M1 layer, a first metal line (M3-1) 114 in a metal-3 (M3) layer, a second metal line (M3-2) 116 in the M3 layer, a first thin film conductive region 118, a second thin film conductive region 120, a first thin film dielectric region 122, and a second thin film dielectric region 124. In some examples, the second thin film dielectric region 124 is (or can be described as) a passivation layer.

Together, the first thin film conductive region 118, the first thin film dielectric region 122, the second thin film conductive region 120, and the second thin film dielectric region 124 form a stacked thin film resistive structure 126. This description of the stacked thin film resistive structure 126 arranges included layers from a bottom layer closest to a semiconductor substrate surface, corresponding to the first thin film conductive region 118, to a top layer closest to an IC device surface, corresponding to the second thin film dielectric region 124.

In some examples, a thin film conductive region 118 or 120 has a thickness between 4 nanometers (nm) and 100 nm (thicknesses are in the z-dimension, unless indicated otherwise). In some examples, a thin film dielectric region 122 or 124 has a thickness between tens of nm and hundreds of nm. In some examples, a dielectric is used that can be deposited at a temperature below 450° Celsius (C).

In some examples, the vias 102, 104, 106, and 108 include tungsten, copper, or other conductive metal. In some examples, the metal lines 110, 112, 114, and 116 include copper, aluminum, or another conductive metal or alloy. In some examples, the thin film conductive regions 118 and 120 include a silicon-carbon-chromium (SiCCr) material, a silicon-chromium (SiCr) material, a metal nitride material such as an atomic layer deposition titanium nitride (ALD TiN) material, or a nickel-chromium (NiCr) material. In some examples, the thin film conductive regions 118 and 120 include a zero temperature coefficient material, such as a zero temperature coefficient material that can be deposited using a chemical vapor deposition (CVD) process. In some examples, a zero temperature coefficient material has a same (or relatively consistent) resistivity over a designated temperature range, such as −40° C. to 120° C. In some examples, the thin film dielectric regions 122 and 124 include an oxide and/or nitride material, such as silicon nitride, silicon oxide, silicon-oxi-nitride, or aluminum oxide.

M1-1 110 is electrically connected to a first end of via1 102. A second end of via1 102 is electrically connected to a first end of the first thin film conductive region 118. M1-2 112 is electrically connected to a first end of via2 104. A second end of via2 104 is electrically connected to a second end of the first thin film conductive region 118. While current flows between M1-1 110 and M1-2 112, and through the first thin film conductive region 118, the first thin film conductive region 118 functions as a first resistor.

M3-1 114 is electrically connected to a first end of via3 106. A second end of via3 106 penetrates through a first end of the second thin film dielectric region 124 to electrically connect to a first end of the second thin film conductive region 120. M3-2 116 is electrically connected to a first end of via4 108. A second end of via4 108 penetrates through a second end of the second thin film dielectric region 124 to electrically connect to a second end of the second thin film conductive region 120. While current flows between M3-1 114 and M3-2 116, through the second thin film conductive region 120, the second thin film conductive region 120 functions as a second resistor.

A dimension from M1-1 110 and M1-2 112 in the M1 layer to M3-1 114 and M3-2 116 in the M3 layer is a z dimension (up, in the page). The z dimension is perpendicular to a substrate surface and/or to a surface of the IC device. A dimension from the first ends to the second ends of the first and second thin film conductive regions 118 and 120 is an x dimension. A dimension perpendicular to the x and z dimensions is a y dimension. Arrows indicating the x, y, and z dimensions relative to structures of the TFR device 100 are included in FIGS. 1 and 3 through 10.

In some examples, the first thin film dielectric region 122 insulates the first resistor from the second resistor. In some examples, the second thin film dielectric layer 124 insulates the second thin film conductive region 120 from other conductive material, such as a metal-2 (M2) layer, deposited on a layer that includes the stacked thin film resistive structure 126. In some examples, the TFR device 100 enables reducing a device area used by a pair of thin film resistors by stacking the first resistor and the second resistor within the same x-y area of the IC device that includes the TFR device 100.

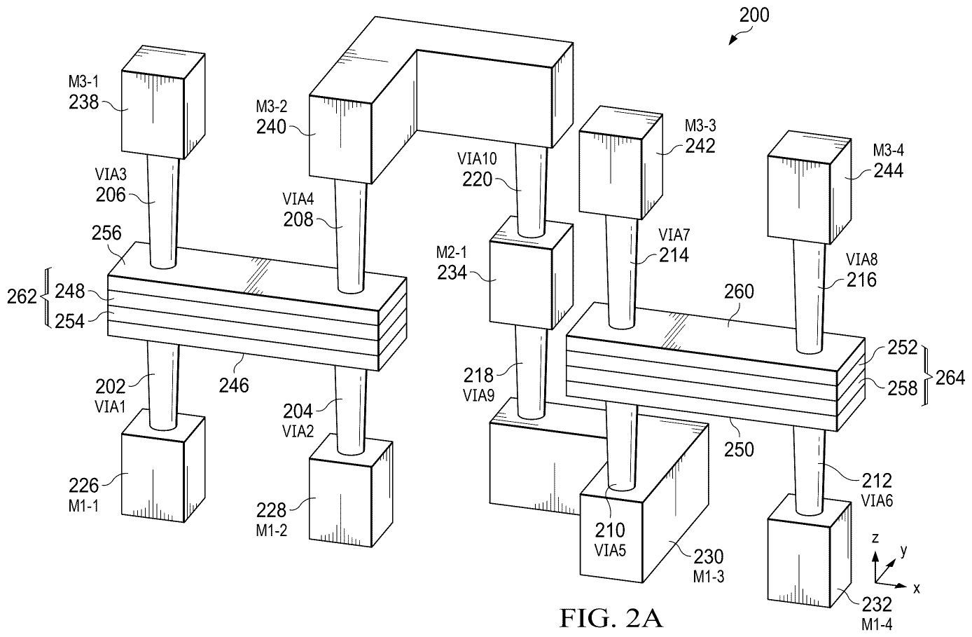

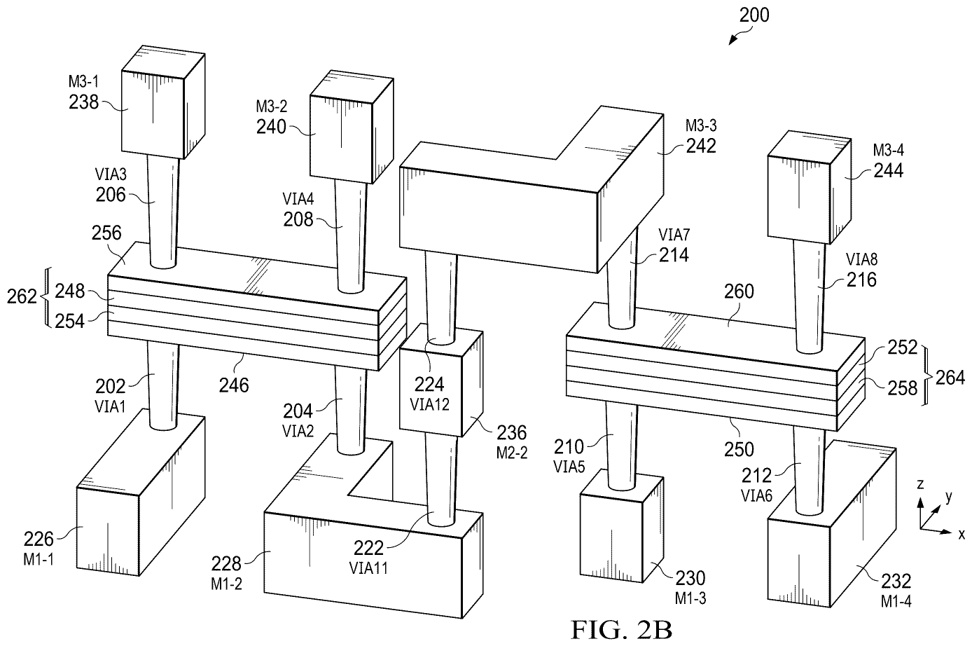

FIG. 2A is a first perspective view of a second example TFR device 200. FIG. 2B is a second perspective view of the TFR device 200 of FIG. 2A. In some examples, the TFR device 200 is included in an IC device that includes a semiconductor substrate and various layers deposited relative to a surface of the substrate, such as metal layers and dielectric layers. The substrate surface, and certain of the metal layers and dielectric layers included in the IC device, are described with respect to FIGS. 2A, 2B, and 11A through 18C.

The components of the TFR device 200 are shown in FIGS. 2A and 2B. For clarity, and as further specified below, some components of the TFR device 200 are shown in FIG. 2A and not FIG. 2B, and some components of the TFR device 200 are shown in FIG. 2B and not FIG. 2A. Some components of the TFR device 200 are shown in both FIGS. 2A and 2B, and have the same item numbering in both figures. Generally, the TFR device 200 includes the stacked layer arrangement of the FIG. 1 TFR device 100, with the change that the device is duplicated so as to provide two resistor stacks, each in co-planar form, and with the above-introduced diagonal connections between the two resistor stacks. Dimensions x, y, and z, and corresponding arrows in the perspective drawing that indicate these dimensions, are described below with reference to described components of the TFR device 200.

The TFR device 200 includes a first via (via1) 202, a second via (via2) 204, a third via (via3) 206, a fourth via (via4) 208, a fifth via (via5) 210, a sixth via (via6) 212, a seventh via (via7) 214, an eighth via (via8) 216, a ninth via (via9) 218, a tenth via (via10) 220, an eleventh via (via11) 222, and a twelfth via (via12) 224. The TFR device 200 further includes a first metal line (M1-1) 226 in the M1 layer, a second metal line (M1-2) 228 in the M1 layer, a third metal line (M1-3) 230 in the M1 layer, a fourth metal line (M1-4) 232 in the M1 layer, a first metal line (M2-1) 234 in a metal-2 (M2) layer, a second metal line (M2-2) 236 in the M2 layer, a first metal line (M3-1) 238 in the M3 layer, a second metal line (M3-2) 240 in the M3 layer, a third metal line (M3-3) 242 in the M3 layer, and a fourth metal line (M3-4) 244 in the M3 layer. The TFR device 200 also includes a first thin film conductive region 246, a second thin film conductive region 248, a third thin film conductive region 250, a fourth thin film conductive region 252, a first thin film dielectric region 254, a second thin film dielectric region 256, a third thin film dielectric region 258, and a fourth thin film dielectric region 260. In some examples, the second thin film dielectric region 124 is (or can be described as) a passivation layer.

The items included in the TFR device 200 that are shown in FIG. 2B and not FIG. 2A are via7 214, via8 216, via11 222, via12 224, a portion of M1-228, M2-2 236, M3-3 242, and M3-4 244.

Together, the first thin film conductive region 246, the first thin film dielectric region 254, the second thin film conductive region 248, and the second thin film dielectric region 256 form a first stacked thin film resistive structure 262. This description of the first stacked thin film resistive structure 262 arranges included layers from a bottom layer closest to a semiconductor substrate surface, corresponding to the first thin film conductive region 246, to a top layer closest to an IC device surface, corresponding to the second thin film dielectric region 256.

Similarly, the third thin film conductive region 250, the third thin film dielectric region 258, the fourth thin film conductive region 252, and the fourth thin film dielectric region 260 form a second stacked thin film resistive structure 264. This description of the second stacked thin film resistive structure 264 arranges included layers from a bottom layer closest to a semiconductor substrate surface, corresponding to the third thin film conductive region 250, to a top layer closest to an IC device surface, corresponding to the fourth thin film dielectric region 260.

In some examples, a thin film conductive region 246, 248, 250, or 252 has a thickness between 4 nanometers (nm) and 100 nm (thicknesses are in the z-dimension, unless indicated otherwise). In some examples, a thin film dielectric region 254, 256, 258, or 260 has a thickness between tens of nm and hundreds of nm.

In some examples, the vias 202, 204, 206, 208, 210, 212, 214, 216, 218, 220, 222, and 224 include tungsten, copper, or other conductive metal(s). In some examples, the metal lines 226, 228, 230, 232, 234, 236, 238, 240, 242, and 244 include copper, aluminum, or another conductive metal or alloy. In some examples, the thin film conductive regions 246, 248, 250, and 252 include a SiCCr material or other material described with respect to the thin film conductive regions 118 and 120 of FIG. 1. In some examples, the thin film dielectric regions 254, 256, 258, and 260 include an oxide and/or nitride material, such as an oxide and/or nitride material described with respect to the thin film dielectric regions 122 and 124 of FIG. 1.

Refer to FIG. 2A. M3-1 238 is electrically connected to a first end of via3 206. A second end of via3 206 penetrates through a first end of the second thin film dielectric region 256 and is electrically connected to a first end of the second thin film conductive region 248. A first end of via4 208 penetrates through a second end of the second thin film dielectric 256 and is electrically connected to a second end of the second thin film conductive region 248. M3-2 240 is electrically connected to a second end of via4 204. A first end of via10 220 is electrically connected to M3-2 240, and a second end of via10 220 is electrically connected to M2-1 234. A first end of via9 218 is electrically connected to M2-2 234, and a second end of via9 218 is electrically connected to M1-3 230. A first end of via5 210 is electrically connected to M1-3 230, and a second end of via5 210 is electrically connected to a first end of the third thin film conductive region 250. A first end of via6 212 is electrically connected to a second end of the third thin film conductive region 250, and a second end of via6 212 is electrically connected to M1-4 232.

Refer to FIG. 2B. M1-1 226 is electrically connected to a first end of via1 202. A second end of via1 202 is electrically connected to a first end of the first thin film conductive region 246. A first end of via2 204 is electrically connected to a second end of the first thin film conductive region 246. M1-2 228 is electrically connected to a second end of via2 204. A first end of via11 222 is electrically connected to M1-2 228, and a second end of via11 222 is electrically connected to M2-2 236. A first end of via12 224 is electrically connected to M2-2 236, and a second end of via12 224 is electrically connected to M3-3 242. A first end of via7 214 is electrically connected to M3-3 242. A second end of via7 214 penetrates through a first end of the fourth thin film dielectric region 260 and is electrically connected to a first end of the fourth thin film conductive region 252. A first end of via8 216 penetrates through a second end of the fourth thin film dielectric region 260 and is electrically connected to a second end of the fourth thin film conductive region 252. A second end of via8 216 is electrically connected to M3-4 244.

While current flows from M1-1 226, through the first thin film conductive region 246, to M1-2 228, to M3-3 242, through the fourth thin film conductive region 252, to M3-4 244, the first and fourth thin film conductive regions 246 and 252 together function as a first resistor. Similarly, while current flows from M3-1 238, through the second thin film conductive region 248, to M3-2 240, to M1-3 230, through the third thin film conductive region 250, to M1-4 232, the second and third thin film conductive regions 248 and 250 together function as a second resistor. Accordingly, the first and fourth thin film conductive regions 246 and 252 are diagonally connected to form the first resistor, and the second and third thin film conductive regions 248 and 250 are diagonally connected to form the second resistor. In some examples, the first and second resistors have matched resistances. In some examples, a resistance of each of the first resistor and the second resistor is between 100 ohms per square and 1000 ohms per square.

In some examples, the first dielectric region 254 insulates the first thin film conductive region 246 from the second thin film conductive region 250. In some examples, the third dielectric region 258 insulates the third thin film conductive region 250 from the fourth thin film conductive region 252. In some examples, the second and fourth dielectric layers 256 and 260 insulate the second and fourth thin film conductive regions 248 and 252 (respectively) from other conductive material, such as the M2 layer, deposited on a layer that includes the stacked thin film resistive structures 262 and 264.

In some examples, and as further described below, each set of same layer, same process type structures included in the TFR device 200, is fabricated responsive to a single photoelectric mask exposure. Same layer refers to structures that are manufactured in a same layer deposited over a semiconductor surface, such as metal lines in a same metal layer, or vias that connect a same pair of metal layers, or a thin film conductive layer or dielectric layer deposited in a same deposition step. Same process refers to structures that are formed responsive to a same set of semiconductor process steps, such as deposition, photoelectric exposure, and etch steps. In an example, same process structures include vias fabricated by depositing conductive material in holes etched in a same inter-level oxide (ILO) layer, where the holes are formed responsive to a single photoelectric exposure step.

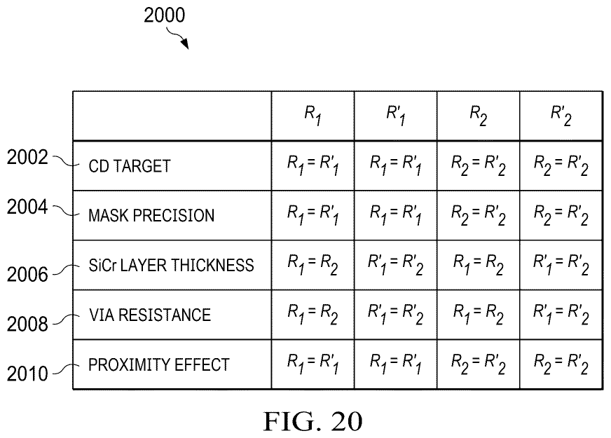

In some examples, same layer, same process type structures include the M1 metal lines 226, 228, 230, and 232, or the vias 206, 208, 214, 216, 220, and 224 that connect the M2 layer to the M3 layer, or the first and third thin film conductive regions 246 and 250, or the second and fourth thin film dielectric regions 256 and 260. In some examples, inclusion of these same layer, same process, single exposure type sets of structures within the first and second resistors enables one or more of various resistance-matching benefits. In some examples, fabrication of portions of the first and second resistors as vertically stacked structures (similar to the TFR device 100 of FIG. 1) enables additional resistance-matching benefits that apply to same-type structures within different, vertically aligned layers. These benefits are further described with respect to FIG. 20.

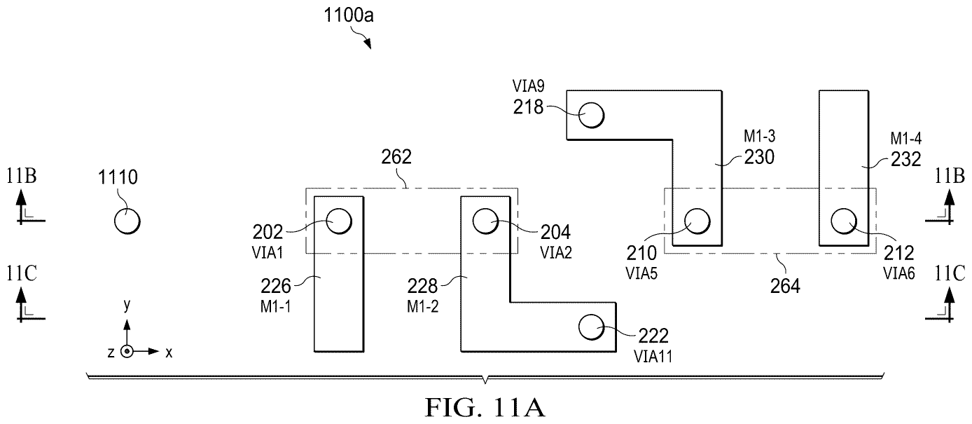

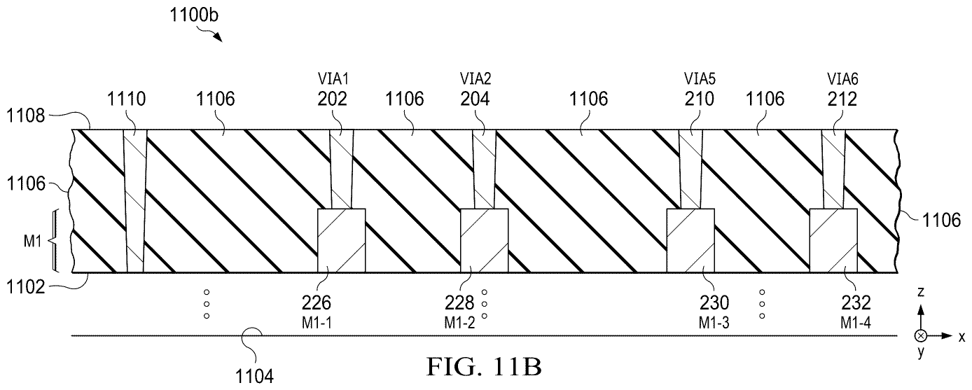

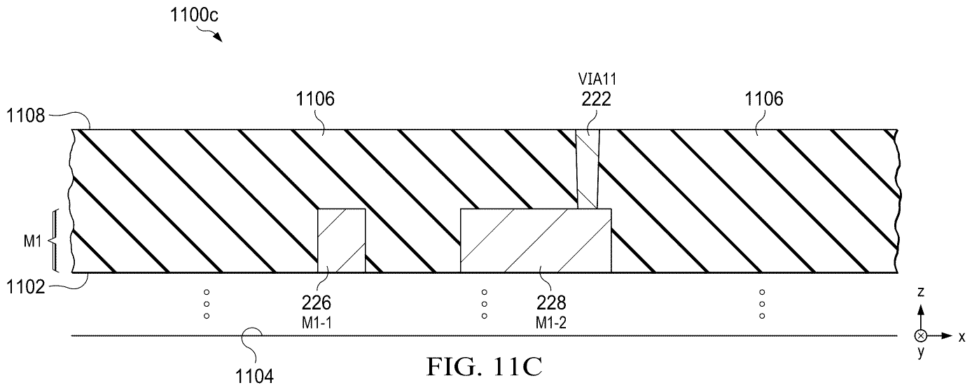

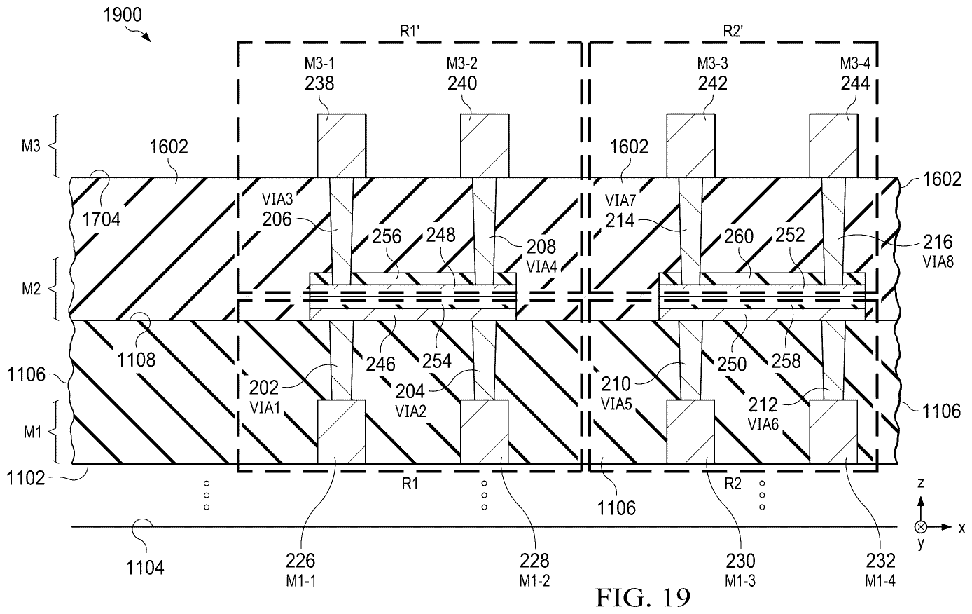

In some examples, diagonal connections between the first and second thin film resistive structures 262 and 264 to form the first and second resistors enable some or all of a first set of benefits. In some examples, fabricating same layer, same process type structures responsive to a single photoelectric mask exposure enables some or all of a second set of benefits. In some examples, the first and second sets of benefits enable a resistance of the first resistor to closely match a resistance of the second resistor. The first and second sets of benefits are further described with respect to FIG. 19, following and in the context of description of FIGS. 11A through 18C.

A dimension from M1-1 226 and M1-2 228 in the M1 layer to M3-1 238 and M3-2 240 in the M3 layer is a z dimension. The z dimension is perpendicular to a substrate surface and/or to a surface of the IC device. A dimension from the first ends to the second ends of the first, second, third, and fourth thin film conductive layers 246, 248, 250, and 252 is an x dimension. A direction perpendicular to the x and z dimensions is a y dimension. Arrows indicating the x, y, and z dimensions relative to structures of the TFR device 200 are included in FIGS. 11A through 18C.

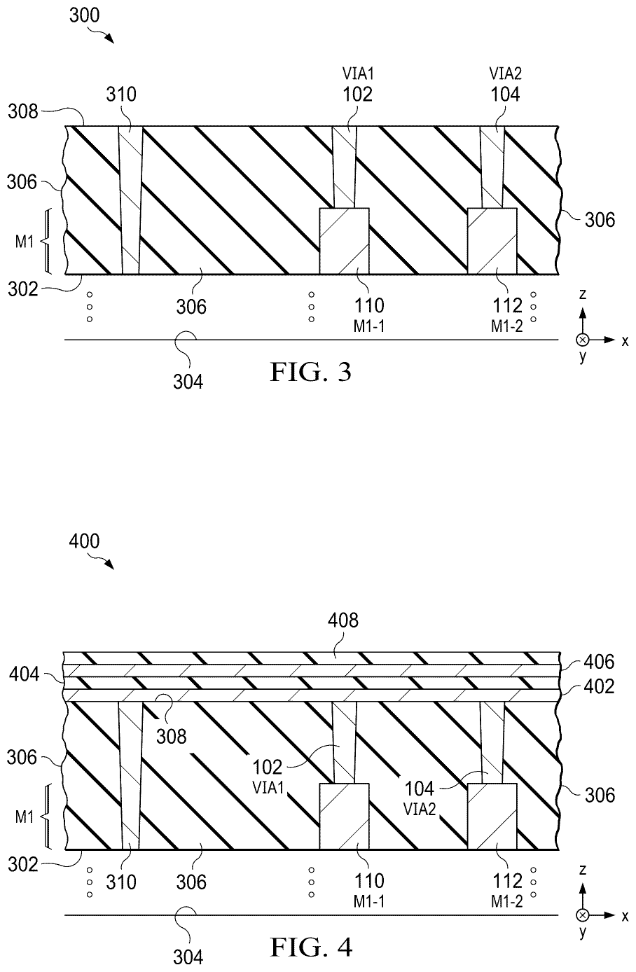

As described above, FIGS. 3 through 10 correspond to semiconductor fabrication process stages and resulting structures corresponding to the TFR device 100 of FIG. 1. FIG. 3 is a partial cross-sectional view 300 representing an example first fabrication stage and resultant structures of the TFR device 100 of FIG. 1. Other process steps can be performed contemporaneously with and/or in addition to the steps described here. In some examples, other process steps can be used to form the structures of the TFR device 100 described herein.

Herein, a boundary layer refers to a layer between a semiconductor substrate surface 304 and an M1 layer of a semiconductor device. A boundary (first) layer surface 302 is located over a boundary layer, which is located over the semiconductor substrate surface 304. An M1 layer is deposited over the first layer surface 302, such as by using a plasma-enhanced CVD process, as may also be the case for deposition of other material layers described below (other than mask layer material). An example metal layer 602 is shown in FIG. 6. A mask (for example, resist) layer is formed over the M1 layer and patterned. In some examples, the mask patterning is performed using a photolithography process, as may also be the case for other mask layers described below. An etch process is performed to remove M1 material not protected by the patterned mask layer, leaving M1-1 110 and M1-2 112, and the remaining mask layer material is removed.

A first inter-level oxide (ILO) layer 306 is formed over the first layer surface 302. A mask layer is formed over the first ILO layer 306 (over a second layer surface 308) and patterned. An etch process is performed to remove ILO material not protected by the mask layer. The etch creates a hole through the ILO and stops at the surface of the layer beneath the first ILO layer 306, accordingly, at the first layer surface 302. Then, the remaining mask layer material is removed.

Conductive via material is formed within the ILO layer 306 holes, which may include a barrier layer and one or more metallization formations. The device is planarized to remove via material in excess of the second layer surface 308, forming via1 102, via2 104, and an additional via 310. In some examples, planarizing corresponds to a chemical mechanical polish (CMP) process. The additional via 310 corresponds to additional routing in an IC that includes the TFR device 100, and is included for context.

FIG. 4 is a partial cross-sectional view 400 representing an example second fabrication stage and resultant structures of the TFR device 100 of FIG. 1. A first thin film conductive material layer 402 is deposited over the second layer surface 308, followed in sequence by a first thin film dielectric material layer 404, a second thin film conductive material layer 406, and a second thin film dielectric material layer 408.

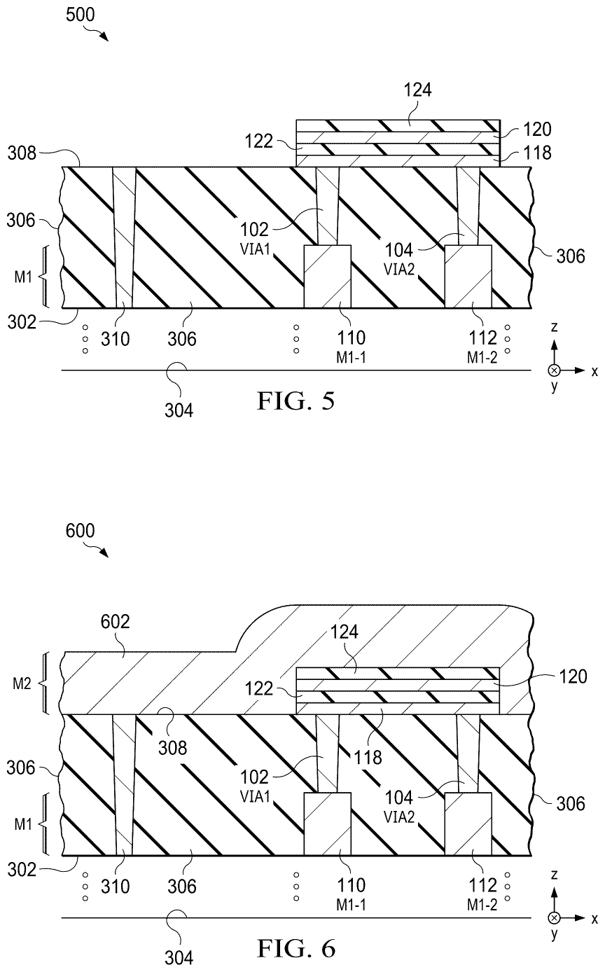

FIG. 5 is a partial cross-sectional view 500 representing an example third fabrication stage and resultant structures of the TFR device 100 of FIG. 1. A mask layer (not shown) is formed over the second layer surface 308 and patterned. An etch process is performed to remove thin film conductive and dielectric material not protected by the patterned mask layer, after which remaining mask layer material is removed. This produces the first and second thin film conductive regions 118 and 120 and the first and second thin film dielectric regions 122 and 124.

FIG. 6 is a partial cross-sectional view 600 representing an example fourth fabrication stage and resultant structures of the TFR device 100 of FIG. 1. An M2 layer 602 is deposited on the second layer surface 308.

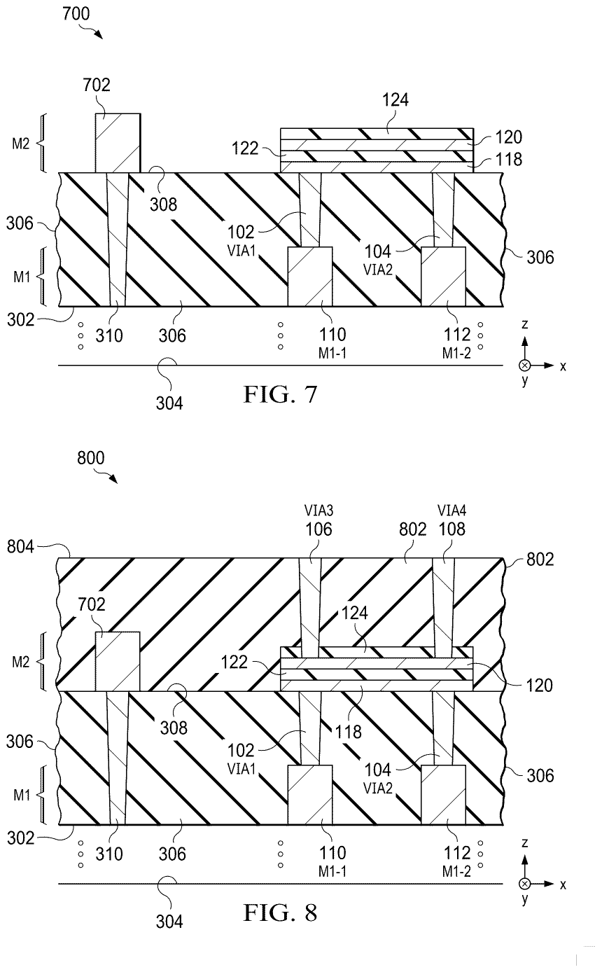

FIG. 7 is a partial cross-sectional view 700 representing an example fifth fabrication stage and resultant structures of the TFR device 100 of FIG. 1. A mask layer is deposited over the M2 layer 602 and patterned. An etch process is performed to fabricate an additional M2 line 702 in electrical contact with the additional via 310, after which remaining mask layer material is removed.

FIG. 8 is a partial cross-sectional view 800 representing an example sixth fabrication stage and resultant structures of the TFR device 100 of FIG. 1. A second ILO layer 802 is deposited, and then a mask layer is deposited over a surface 804 of the second ILO layer 802 (a third layer surface 804). The mask layer is patterned, and an etch process is performed that creates two corresponding holes and stops at a surface of the second thin film conductive region 120. Accordingly, the etch penetrates, in two different locations, through a portion of the second ILO layer 802 and through the thin film dielectric region 124. Remaining mask layer material is removed. Conductive via material is formed within the second ILO layer 802 and second thin film dielectric region 124 holes. Via material in excess of the third layer surface 804 is removed by planarization, leaving via3 106 and via4 108 in the holes left by the etch process.

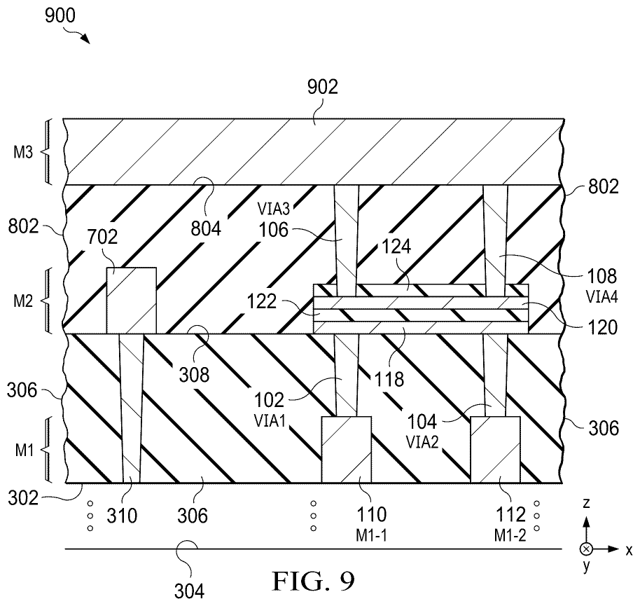

FIG. 9 is a partial cross-sectional view 900 representing an example seventh fabrication stage and resultant structures of the TFR device 100 of FIG. 1. An M3 layer 902 is deposited on the third layer surface 804.

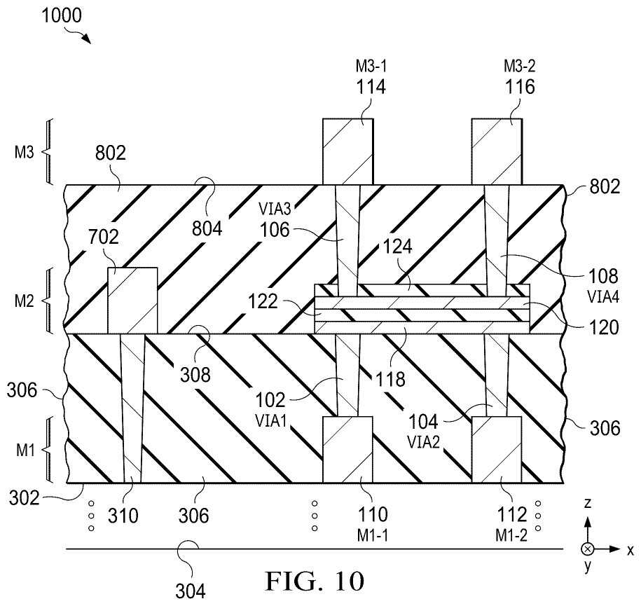

FIG. 10 is a partial cross-sectional view 1000 representing an example eighth fabrication stage and resultant structures of the TFR device 100 of FIG. 1. A mask layer is formed over the M3 layer and patterned. An etch process is performed to remove M3 material not protected by the patterned mask layer, leaving M3-1 114 and M3-2 116, and the remaining mask layer material is removed.

As described above, FIGS. 11A through 18C correspond to semiconductor fabrication process stages and resulting structures corresponding to the TFR device 200 of FIGS. 2A and 2B. FIG. 11A is a top-down view 1100a representing an example first fabrication stage and resultant structures of the TFR device 200 of FIGS. 2A and 2B. FIG. 11B is a partial cross-sectional view 1100b taken across a first line in FIG. 11A. FIG. 11C is a partial cross-sectional view 1100c taken across a second line in FIG. 11A. Other process steps can be performed contemporaneously with and/or in addition to the steps described here. In some examples, other process steps can be used to form the structures of the TFR device 200.

A boundary (first) layer surface 1102 is located over a boundary layer, which is located over a semiconductor substrate surface 1104. An M1 layer is deposited over the first layer surface 1102. (Accordingly, the boundary layer is located between the semiconductor substrate surface 1102 and the M1 layer.) A mask layer is formed over the M1 layer and patterned. An etch process is performed to remove M1 material not protected by the patterned mask layer, leaving M1-1 226, M1-2 228, M1-3 230, and M1-4 232. The remaining mask layer material is removed. In some examples, the same photoelectric mask exposure(s) patterns the mask layer portion responsive to which M1-1 226, M1-2 228, M1-3 230, and M1-4 232 are fabricated.

A first ILO layer 1106 is formed over the first layer surface 1102. A mask layer is formed over the first ILO layer 1106 and M1 structures (over a second layer surface 1108) and patterned. An etch process is performed to form holes through ILO material not protected by the mask layer, after which remaining mask layer material is removed. Conductive via material is formed within the ILO layer 1106 holes, which may include a barrier layer and one or more metallization formations. The device is planarized to remove via material in excess of the second layer surface 1108, forming via1 202, via2 204, via5 210, via6 212, via9 218, via10 220, and an additional via 1110. The additional via 1110 corresponds to additional routing in an IC that includes the TFR device 200, and is included for context. In some examples, the same photoelectric mask exposure(s) patterns the mask layer portion responsive to which via1 202, via2 204, via5 210, via6 212, via9 218, and via10 220 are fabricated.

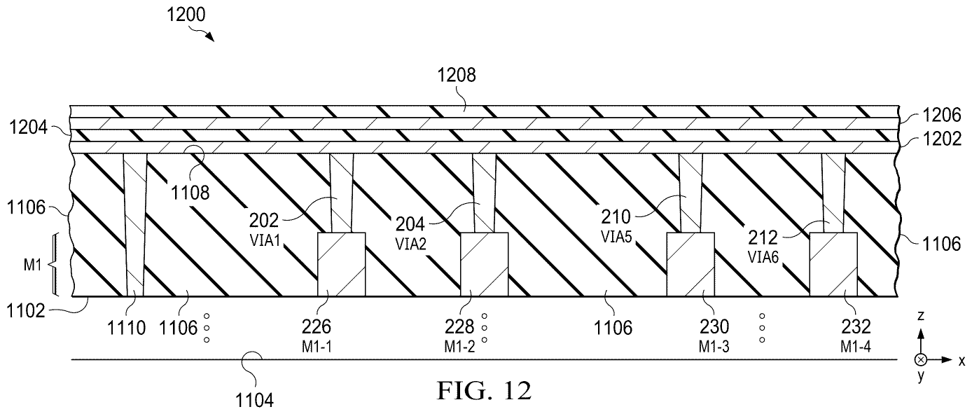

FIG. 12 is a partial cross-sectional view 1200 representing an example second fabrication stage and resultant structures of the TFR device 200 of FIGS. 2A and 2B. A first thin film conductive material layer 1202 is deposited over the second layer surface 1108, followed in sequence by a first thin film dielectric material layer 1204, a second thin film conductive material layer 1206, and a second thin film dielectric material layer 1208.

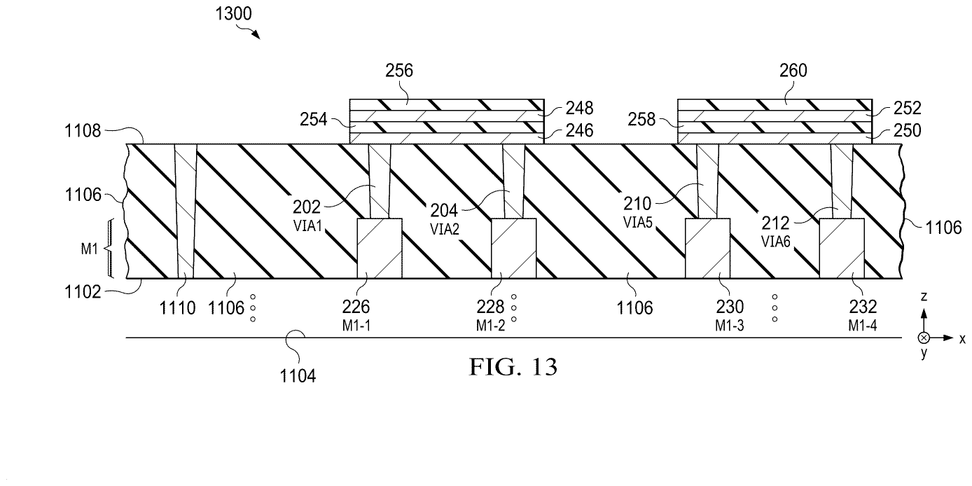

FIG. 13 is a partial cross-sectional view 1300 representing an example third fabrication stage and resultant structures of the TFR device 200 of FIGS. 2A and 2B. A mask layer is formed over the second layer surface 1108 and patterned. An etch process is performed to remove thin film conductive and dielectric material not protected by the patterned mask layer, after which remaining mask layer material is removed. This produces the first, second, third, and fourth thin film conductive regions 246, 248, 250, and 252 and the first, second, third, and fourth thin film dielectric regions 254, 256, 258, and 260. In some examples, the same photoelectric mask exposure(s) patterns the mask layer portion responsive to which the first, second, third, and fourth thin film conductive regions 246, 248, 250, and 252 and the first, second, third, and fourth thin film dielectric regions 254, 256, 258, and 260 are fabricated.

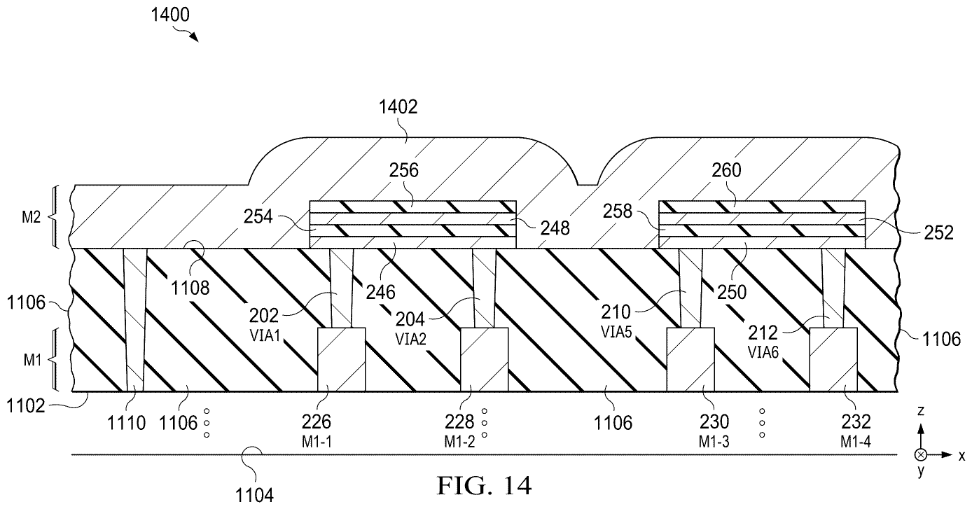

FIG. 14 is a partial cross-sectional view 1400 representing an example fourth fabrication stage and resultant structures of the TFR device 200 of FIGS. 2A and 2B. An M2 layer 1402 is deposited on the second layer surface 1108.

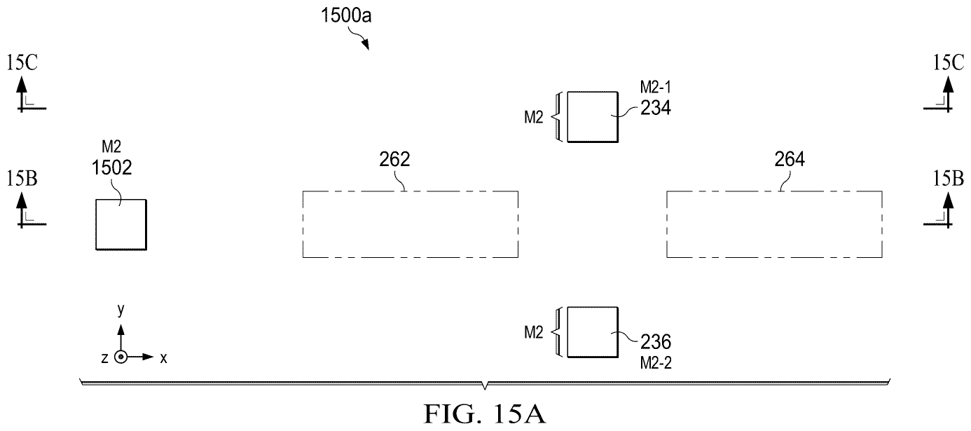

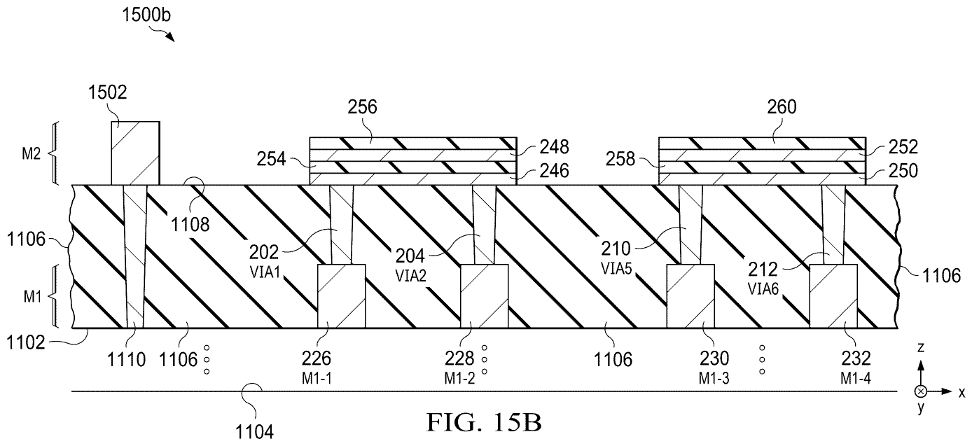

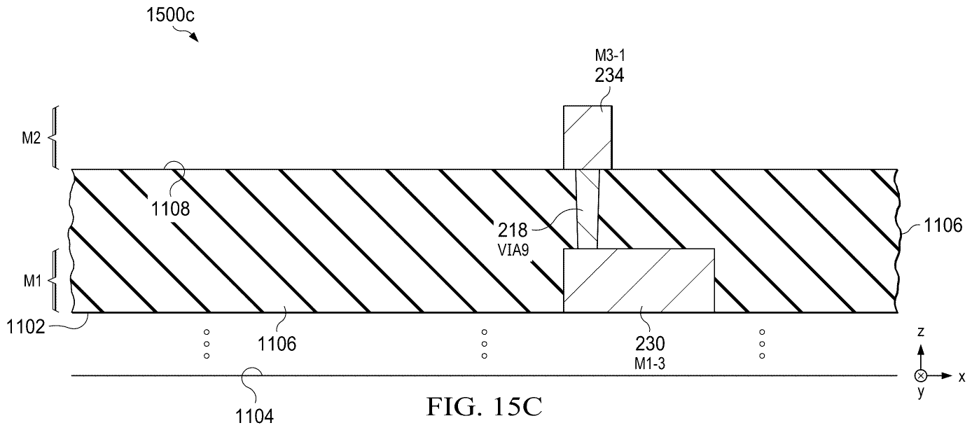

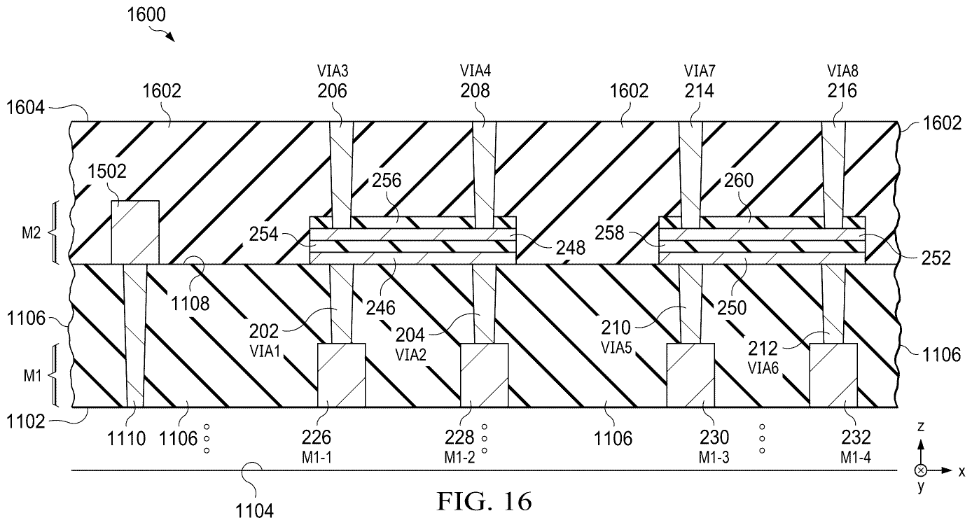

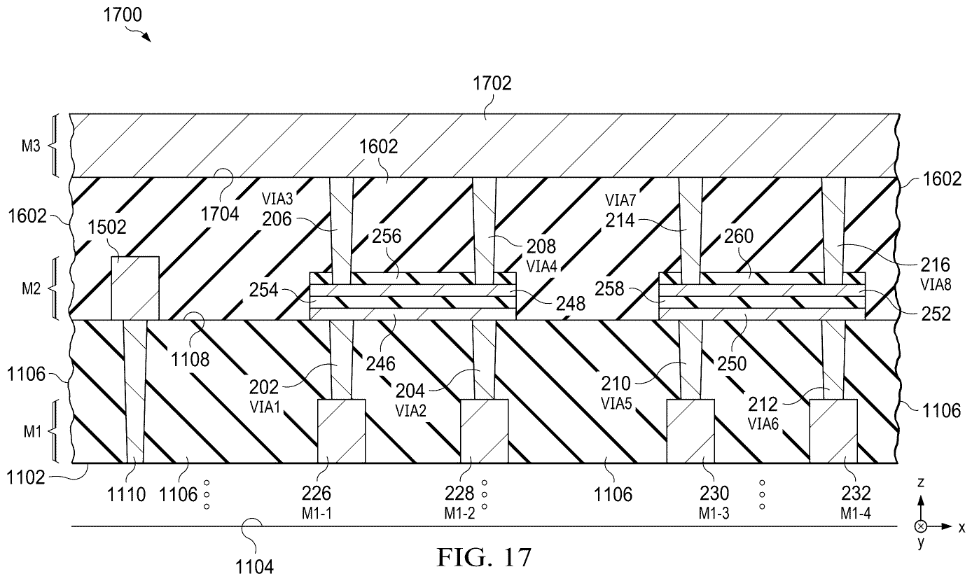

FIG. 15A is a top-down view 1500a representing an example fifth fabrication stage and resultant structures of the TFR device 200 of FIGS. 2A and 2B. FIG. 15B is a partial cross-sectional view 1500b taken across a first line in FIG. 15A. FIG. 15C is a partial cross-sectional view 1500c taken across a second line in FIG. 15A.

A mask layer is deposited over the M2 layer 1402 and patterned. An etch process is performed to fabricate M2-1 234 and M2-2 236, and also an additional M2 line 1502 that is in electrical contact with the additional via 1110. The remaining mask layer material is removed. In some examples, the same photoelectric mask exposure(s) patterns the mask layer portion responsive to which M2-1 234 and M2-2 236 are fabricated.

FIG. 16 is a partial cross-sectional view 1600 representing an example sixth fabrication stage and resultant structures of the TFR device 200 of FIGS. 2A and 2B. A second ILO layer 1602 is deposited, and then a mask layer is deposited over a surface 1604 of the second ILO layer 1602 (a third layer surface 1604). The mask layer is patterned, and an etch process forming holes is performed that stops at the second and fourth thin film conductive regions 248 and 252 (while not shown, an additional hole may be etched to the additional M2 line 1502). Remaining mask layer material is removed, and then conductive via material is deposited to fill the holes in the second ILO layer 1602 and the second and fourth thin film dielectric regions 256 and 260. Via material in excess of the third layer surface 804 is removed by planarization, leaving via3 206, via4 208, via7 214, via8 216, via10 220, and via12 224 in the holes formed by the etch process. In some examples, the same photoelectric mask exposure(s) patterns the mask layer portion responsive to which via3 206, via4 208, via7 214, via8 216, via10 220, and via12 224 are patterned.

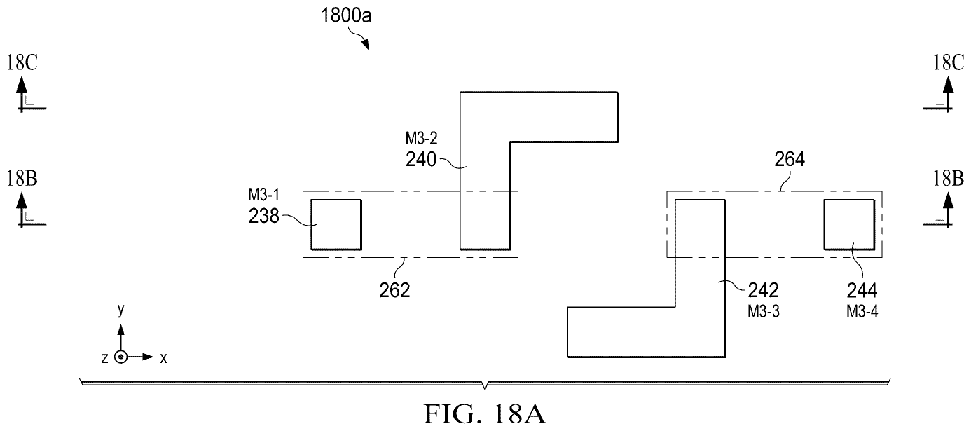

FIG. 17 is a partial cross-sectional view 1700 representing an example seventh fabrication stage and resultant structures of the TFR device 200 of FIGS. 2A and 2B. An M3 layer 1702 is deposited on the third layer surface 1704.

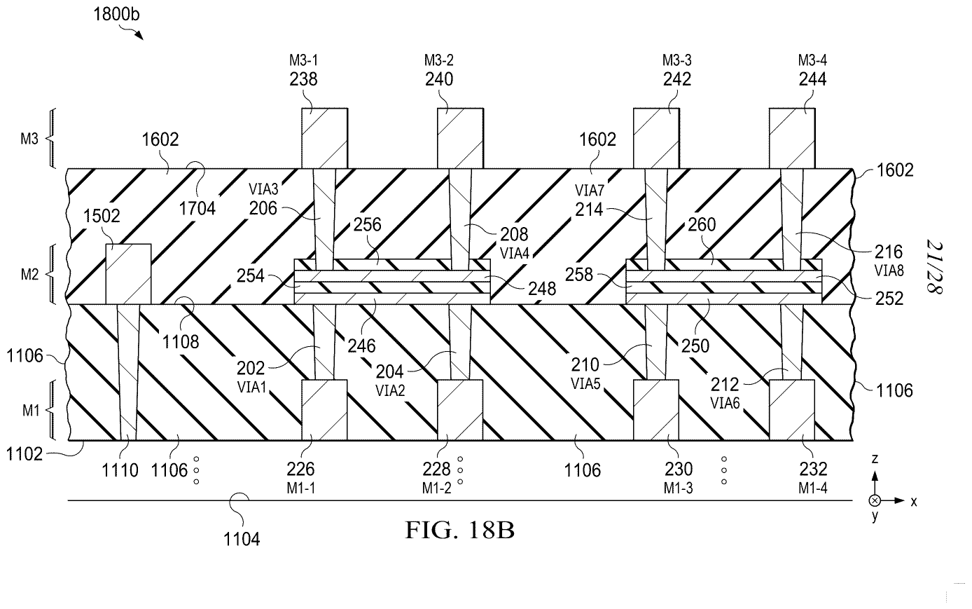

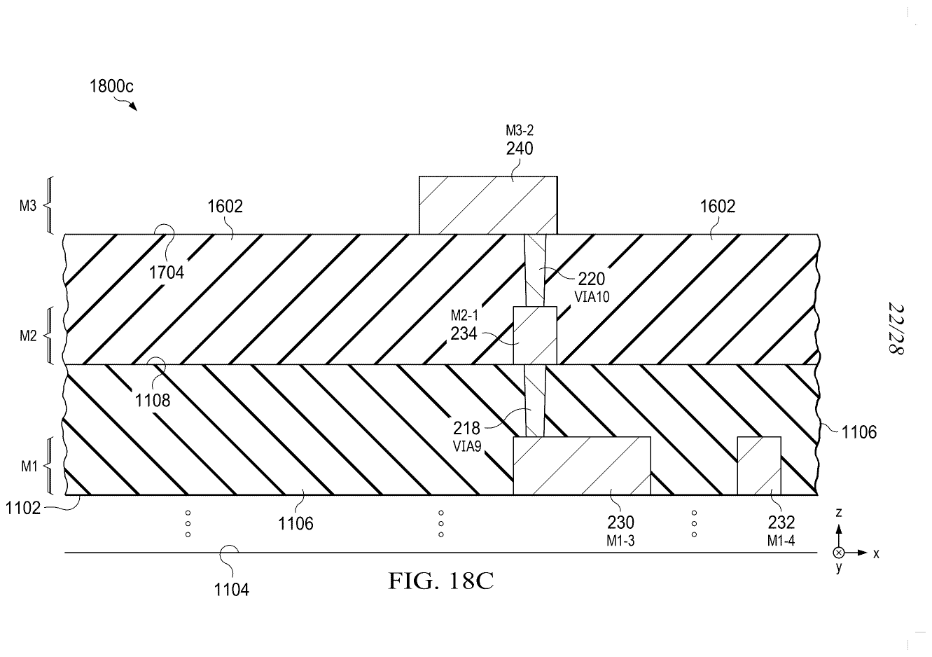

FIG. 18A is a top-down view 1800a representing an example eighth fabrication stage and resultant structures of the TFR device 200 of FIGS. 2A and 2B. FIG. 18B is a partial cross-sectional view 1800b taken across a first line in FIG. 18A. FIG. 18C is a partial cross-sectional view 1800c taken across a second line in FIG. 18A.

A mask layer is formed over the M3 layer and patterned. An etch process is performed to remove M3 material not protected by the patterned mask layer, leaving M3-1 238, M3-2 240, M3-3 242, and M3-4 244, and the remaining mask layer material is removed. In some examples, the same photoelectric mask exposure(s) patterns the mask layer portion responsive to which M3-1 238, M3-2 240, M3-3 242, and M3-4 244 are patterned.

FIG. 19 is a partial cross-sectional view 1900 of the TFR device 200 of FIGS. 2A and 2B. The TFR device 200 is divided into four portions, labeled R1, R1′ (R1 prime), R2, and R2′. This division facilitates description of one or more benefits that (in some examples) may be provided by the fabrication process that forms the TFR device 200, and the diagonal connections that form the first and second resistors, as described above. Description of these benefits is provided with respect to FIG. 20.

R1 includes M1-1 226, M1-2 228, via1 202, via2 204, the first thin film conductive region 246, and the first thin film dielectric region 254. R1′ includes M3-1 238, M3-2 240, via3 206, via4 208, the second thin film conductive region 248, and the second thin film dielectric region 256. R2 includes M1-3 230, M1-4 232, via5 210, via6 212, the third thin film conductive region 250, and the third thin film dielectric region 258. R2′ includes M3-3 242, M3-4 244, via7 214, via8 216, the fourth thin film conductive region 252, and the fourth thin film dielectric region 260.

FIG. 20 is a table describing some example benefits of the TFR device 200 of FIGS. 2A and 2B, fabricated as described with respect to FIGS. 11A through 18C. In some examples, portions of the substrate on which the TFR device 200 is fabricated that are illuminated by photoelectric exposure for fabrication of structures in R1 are aligned with portions of the wafer illuminated by photoelectric exposure for fabrication of structures in R1′. Similarly, portions of the wafer illuminated by photoelectric exposure for fabrication of structures in R1 are aligned with portions of the wafer illuminated by photoelectric exposure for fabrication of structures in R1′. Also, as described above, same layer same type structures of the TFR device 200 (such as in the first and second stacked thin film resistive structures 262 and 264) are fabricated responsive to same photoelectric exposure(s) of same mask(s).

These process rules, with the structures and connections described above, lead to some or all of various benefits corresponding to matching characteristics of various combinations of R1, R1′, R2, and R2′. These characteristics are grouped into five categories, corresponding to the five rows of the table 2000: critical dimension (CD) target 2002, mask precision (CD error on the photo mask) 2004, SiCCr layer thickness 2006, via resistance 2008, and proximity effect 2010. Matches between these characteristics enable more closely matched resistance between the first resistor and the second resistor, as further described below.

CD target 2002, mask precision 2004, and proximity effect 2010 are matched between thin film conductive and dielectric regions 246, 248, 254, and 256 of the lower (R1) and upper (R1′) portions of the first thin film resistive structure 262. CD target 2002, mask precision 2004, and proximity effect 2010 are also matched between thin film conductive and dielectric regions 250, 252, 258, and 260 of the lower (R2) and upper (R2′) portions of the second thin film resistive structure 264. In some examples, critical dimension (CD) target 2002 and mask precision 2004 are matched because the same photomask step is used to generate resist pattern corresponding to same process type structures in R1 as in R1′, and in R2 as in R2′. This facilitates precise (or exact) matching between same process type structures in R1 and R1′, and in R2 and R2′, with respect to horizontal geometries. Accordingly, precise (or exact) matching is enabled in respective x-y planes. In some examples, proximity effect 2010 is matched because components within a single thin film resistive structure 262 or 264 share locality.

In some examples, resistances of the first and second resistors are sufficiently large that differences between via resistances are sufficiently small that they do not interfere with design requirements for precision of the resistors. In some examples, resistance of an individual via is in the single digit Ohm range, and via resistance variability is in the milliOhm to tens of milliOhms range. In some examples, resistances of the first and second resistors are each in the range of 1 kilohm to 1 megaohm. Accordingly, in some examples, via resistance variability can be described as negligible, and via resistance can be described as being matched between different portions of the thin film resistive structures 262 and 264. In some examples, structures and systems described herein have different resistances than described.

SiCCr layer thickness 2006 and via resistance 2008 are matched between the lower (R1) portion of the first thin film resistive structure 262 and the lower (R2) portion of the second thin film resistive structure 264. SiCCr layer thickness 2006 and via resistance 2008 are also matched between the upper (R1′) portion of the first thin film resistive structure 262 and the upper (R2′) portion of the second thin film resistive structure 264. In some examples, SiCCr layer thickness 2006 is matched because deposition of SiCCr layers is performed responsive to a single mask exposure and in a same CVD step. In some examples, via resistance 2008 matching is improved because deposition of vias of a single layer (for example, above M1 or above M2) is performed responsive to a single mask exposure and in a same CVD step.

Also, the thin film conductive regions 246, 248, 250, and 252 and the thin film dielectric regions 254, 256, 258, and 260 are fabricated responsive to a single mask exposure, and regions within the same layer are deposited in same CVD steps. Regions in same layers include the first and third thin film conductive regions 246 and 250, the second and fourth thin film conductive regions 248 and 252. Regions in same layers also include the first and third thin film dielectric regions 254 and 258, and the second and fourth thin film dielectric regions 256 and 260.

Responsive to diagonal connections forming the first and second resistors, the first and second resistors have matching CD target 2002, mask precision 2004, SiCCr layer thickness 2006, via resistance 2008, and proximity effect 2010. The first resistor can be expressed as R1+R2′, and the second resistor can be expressed as R1′+R2. Here, + indicates total resistance in series of described regions with corresponding interconnections (vias and metal lines). Features forming these electrical connections match for similar reasons to those described with respect to features of R1, R1′, R2, and R2′.

As described above, for CD target 2002, mask precision 2004, and proximity effect 2010, R1=R1′ and R2=R2′. For SiCCr layer thickness 2006 and via resistance 2008, R1=R2 and R1′=R2′. These equalities enable substitutions that show that the first resistor and second resistor are matched across each of the described factors.

With respect to CD target 2002, mask precision 2004, and proximity effect 2010, R1+R2′ of the first resistor equals R1+R2, and R1′+R2 of the second resistor also equals R1+R2. With respect to SiCCr layer thickness 2006 and via resistance 2008, R1+R2′ of the first resistor equals R1+R1′, and R1′+R2 of the second resistor also equals R1+R1′, so that the first resistor matches the second resistor.

In some examples, use of multiple separate thin film conductive regions 246, 248, 250, and/or 252 from different deposition layers in each of the first and second resistors increases the chance of stochastic variations in layer thickness averaging out to reach a total resistance closer to a designed value than would be reached by a single region.

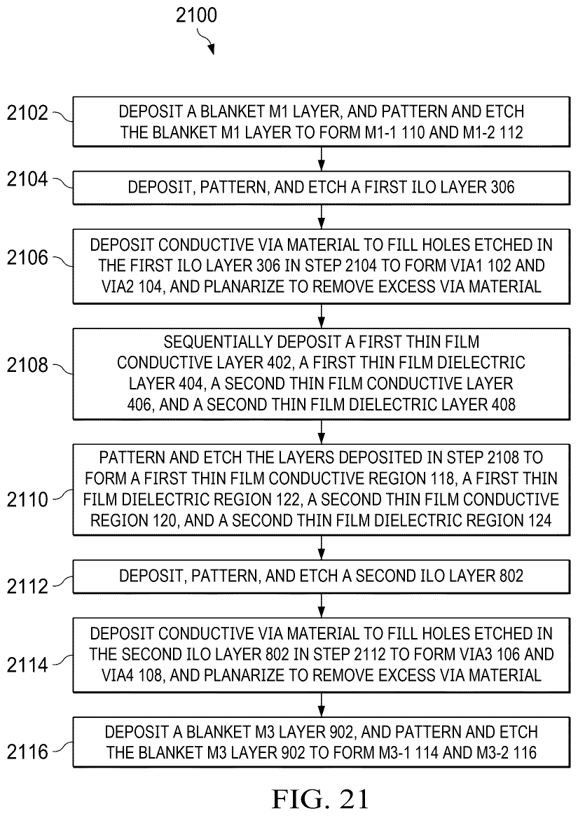

FIG. 21 is a flow diagram of a process 2100 for fabricating the TFR device 100 of FIG. 1. In step 2102, deposit an M1 layer, and pattern and etch the M1 layer to form M1-1 110 and M1-2 112. In step 2104, deposit, pattern, and etch a first ILO layer 306. In step 2106, deposit conductive via material to fill holes etched in the first ILO layer 306 in step 2104 to form via1 102 and via2 104, and planarize to remove excess via material.

In step 2108, sequentially deposit a first thin film conductive layer 402, a first thin film dielectric layer 404, a second thin film conductive layer 406, and a second thin film dielectric layer 408. In step 2110, pattern and etch the layers deposited in step 2108 to form a first thin film conductive region 118, a first thin film dielectric region 122, a second thin film conductive region 120, and a second thin film dielectric region 124.

In step 2112, deposit, pattern, and etch a second ILO layer 802. In step 2114, deposit conductive via material to fill holes etched in the second ILO layer 802 in step 2112 to form via3 106 and via4 108, and planarize to remove excess via material. In step 2116, deposit an M3 layer 902, and pattern and etch the M3 layer 902 to form M3-1 114 and M3-2 116.

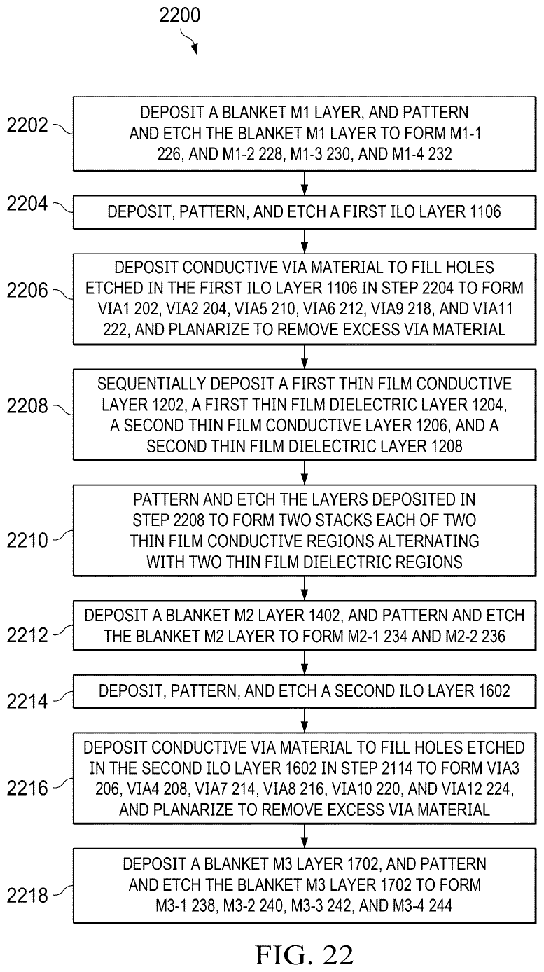

FIG. 22 is a flow diagram of a process 2200 for fabricating the TFR device 200 of FIGS. 2A and 2B. In step 2202, deposit an M1 layer, and pattern and etch the M1 layer to form M1-1 226, and M1-2 228, M1-3 230, and M1-4 232. In step 2204, deposit, pattern, and etch a first ILO layer 1106. In step 2206, deposit conductive via material to fill holes etched in the first ILO layer 1106 in step 2204 to form via1 202, via2 204, via5 210, via6 212, via9 218, and via11 222, and planarize to remove excess via material.

In step 2208, sequentially deposit a first thin film conductive layer 1202, a first thin film dielectric layer 1204, a second thin film conductive layer 1206, and a second thin film dielectric layer 1208. In step 2210, pattern (in some examples, using a single photoelectric mask exposure) and etch the layers deposited in step 2208 to form two stacks each of two thin film conductive regions alternating with two thin film dielectric regions. The first stack includes a first thin film conductive region 246, a first thin film dielectric region 254, a second thin film conductive region 248, and a second thin film dielectric region 256. The second stack includes a third thin film conductive region 250, a third thin film dielectric region 258, a fourth thin film conductive region 252, and a fourth thin film dielectric region 260.

In step 2212, deposit an M2 layer 1402, and pattern and etch the M2 layer to form M2-1 234 and M2-2 236. In step 2214, deposit, pattern, and etch a second ILO layer 1602. In step 2216, deposit conductive via material to fill holes etched in the second ILO layer 1602 in step 2214 to form via3 206, via4 208, via7 214, via8 216, via10 220, and via12 224, and planarize to remove excess via material. In step 2218, deposit an M3 layer 1702, and pattern and etch the M1 layer 1702 to form M3-1 238, M3-2 240, M3-3 242, and M3-4 244.

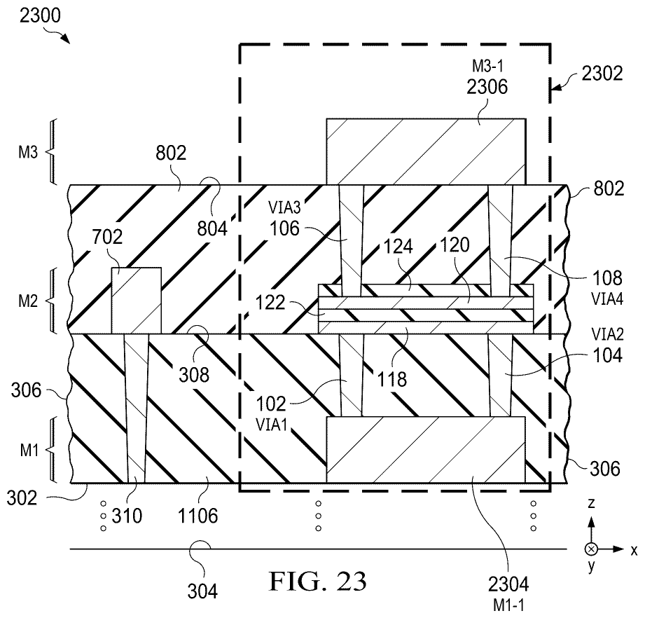

FIG. 23 is a partial cross-sectional view 2300 representing a modification of the TFR device 100 of FIG. 1 to form a capacitor 2302. The capacitor 2302 includes an M1 line (M1-1) 2304 and an M3 line (M3-1) 2306. M1-1 2304 is electrically connected to a first end of via1 102 and a first end of via2 104. A second end of via1 102 is electrically connected to a first end of the first thin film conductive region 118. A second end of via2 104 is electrically connected to a second end of the first thin film conductive region 118. M3-1 2306 is electrically connected to a first end of via3 106 and a first end of via4 108. A second end of via3 106 penetrates through the second thin film dielectric region 124 to connect to a first end of the second thin film conductive region 120. A second end of via4 108 penetrates through the second thin film dielectric region 124 to connect to a second end of the second thin film conductive region 120.

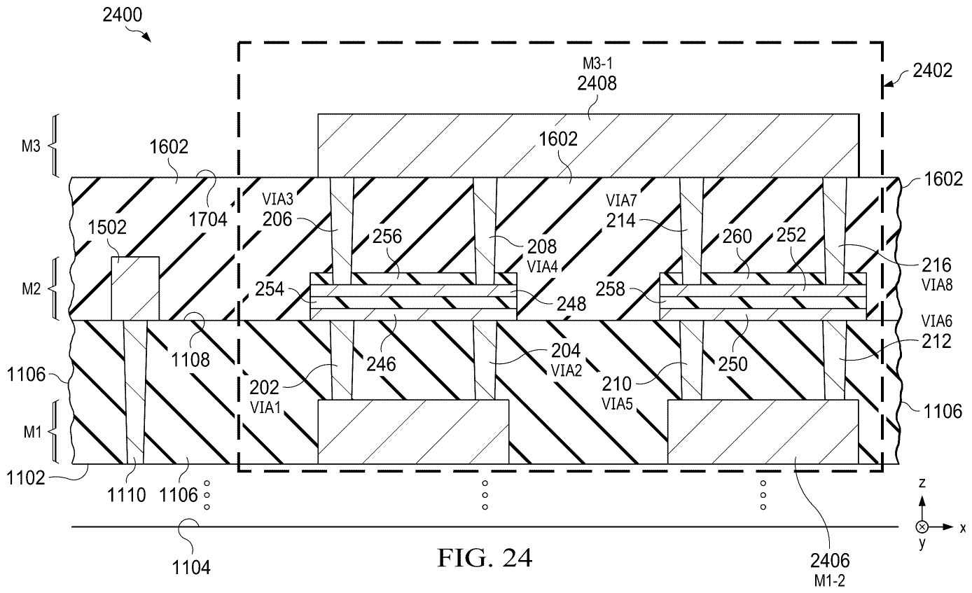

FIG. 24 is a partial cross-sectional view 2400 representing a modification of the TFR device 200 of FIG. 2 to form a capacitor 2402. The capacitor 2402 includes a first M1 line (M1-1) 2404, a second M1 line (M1-2) 2406, and an M3 line (M3-1) 2406.

M1-1 2304 is electrically connected to a first end of via1 202 and a first end of via2 204. A second end of via1 202 is electrically connected to a first end of the first thin film conductive region 246. A second end of via2 204 is electrically connected to a second end of the first thin film conductive region 246. M1-2 2406 is electrically connected to a first end of via5 210 and a first end of via6 212. A second end of via5 210 is electrically connected to a first end of the third thin film conductive region 250. A second end of via6 212 is electrically connected to a second end of the third thin film conductive region 250.

M3-1 2408 is electrically connected to a first end of via3 206, a first end of via4 208, a first end of via7 214, and a first end of via8 216. A second end of via3 206 penetrates through the second thin film dielectric region 256 to connect to a first end of the second thin film conductive region 248. A second end of via4 208 penetrates through the second thin film dielectric region 256 to connect to a second end of the second thin film conductive region 248. A second end of via7 214 penetrates through the fourth thin film dielectric region 260 to connect to a first end of the fourth thin film conductive region 252. A second end of via8 216 penetrates through the fourth thin film dielectric region 260 to connect to a second end of the fourth thin film conductive region 252.

Herein, layer refers to a structure formed by CVD or other material deposition process. Region refers to a structure formed from a layer following photoelectric mask exposure, patterning, and etch, or following other pattern-forming process. Electrically couple refers to a physical connection enabling electron flow between the coupled structures. A metal line refers to a contact, trace, or other primary horizontally-oriented (relative to the substrate surface) conductive metal structure within a metal layer (such as M1, M2, etc.). A via refers to a primary vertically oriented (relative to the substrate surface) conductive structure electrically connecting structures in different metal layers (such as M1 and M2, M2 and M3, etc.).

In some examples, the first stacked thin film resistive structure 262 and the second stacked thin film resistive structure 264 are arranged end to end, accordingly, so that short sides (in an x-y plane) of the first and second stacked thin film resistive structures 262 and 264 are near each other. In some examples, the first stacked thin film resistive structure 262 and the second stacked thin film resistive structure 264 are arranged side by side, accordingly, so that long sides (in the x-y plane) of the first and second stacked thin film resistive structures 262 and 264 are near each other. In some examples, vias connected to conductive regions of a stacked thin film resistive structure are disposed so that current flow is parallel to a long axis (in the x-y plane) of the stacked thin film resistive structure. In some examples, vias are disposed so that current flow is not parallel to the long axis of the stacked thin film resistive structure. In some examples, the sides (in the x-y plane) of each of the first and second stacked thin film resistive structures 262 and 264 are the same length.

In some examples, a thin film conductive layer or region, or a thin film dielectric layer or region, is a different thickness than described herein.

In some examples, resistors fabricated as described herein are used for applications other than those described herein.

In some examples, described structures are formed in layers further from a substrate surface (such as metal-4 or metal-5 instead of metal-3) than described herein.

In some examples, a stacked resistive structure that includes two thin film conductive regions separated in a z dimension by a thin film dielectric region does not include a second thin film dielectric region fabricated over (such as in contact with) a later-deposited one of the thin film conductive regions. In some examples, a different insulator or different type of dielectric layer (accordingly, other than a thin film) is deposited over the later-deposited one of the thin film conductive regions. In some examples, a material other than an insulator is deposited after and in contact with the later-deposited one of the thin film conductive regions.

In some examples, a thin film dielectric region deposited over a thin film conductive region is referred to as overlying the thin film conductive region. Specifically, a thin film dielectric region overlying a thin film conductive region sufficiently covers the thin film conductive region as to insulate the thin film conductive region from material deposited after or on top of the thin film dielectric region.

In some examples, a thin film conductive region deposited over a thin film dielectric region is referred to as overlying the thin film dielectric region. Specifically, a thin film conductive region overlying a thin film dielectric region is sufficiently covered on a lower surface by the thin film dielectric region as to insulate the thin film conductive region from material deposited prior to or below the thin film dielectric region.

In some examples, one or more chains of vias are used. In some examples, or one or more via stripes are used. In some examples, using via chains or via stripes reduces a via resistance dependency of corresponding resistors according to the thin film resistor device 100 of FIG. 1A or the thin film resistor device 200 of FIGS. 2A and 2B. In some examples, a mask specification includes tighter tolerances with respect to features corresponding to vias to reduce a via resistance dependency according to a thin film resistor device 100 or 200. In some examples, mask-related error contributes between 5% and 15% of a total CD error for a device layer.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

A device that is “configured to” perform a task or function may be configured (for example, programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

A circuit or device that is described herein as including certain components may instead be adapted to be coupled to those components to form the described circuitry or device. For example, a structure described as including multiple functional blocks may instead include only the functional blocks within a single physical device (for example, a semiconductor die and/or integrated circuit (IC) package) and may be adapted to be coupled to at least some of the functional blocks to form the described structure either at a time of manufacture or after a time of manufacture, for example, by an end-user and/or a third-party.

Circuits described herein are reconfigurable to include the replaced components to provide functionality at least partially similar to functionality available prior to the component replacement.

The term “couple” is used throughout the specification. The term may cover connections, communications, or signal paths that enable a functional relationship consistent with this description. For example, if device A provides a signal to control device B to perform an action, in a first example device A is coupled to device B, or in a second example device A is coupled to device B through intervening component C if intervening component C does not substantially alter the functional relationship between device A and device B such that device B is controlled by device A via the control signal provided by device A.

While certain elements of the described examples may be included in an IC and other elements are external to the IC, in other examples, additional or fewer features may be incorporated into the IC. In addition, some or all of the features illustrated as being external to the IC may be included in the IC and/or some features illustrated as being internal to the IC may be incorporated outside of the IC. As used herein, the term “IC” means one or more circuits that are: (i) incorporated in/over a semiconductor substrate; (ii) incorporated in a single semiconductor package; (iii) incorporated into the same module; and/or (iv) incorporated in/on the same PCB.

Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. A device, comprising:
a first thin film conductive region having a first end, a second end, a first surface, and a second surface;
a second thin film conductive region having a first end, a second end, a first surface, and a second surface;
a thin film dielectric region having a first surface and a second surface, the first surface of the thin film dielectric region coupled to the first surface of the first thin film conductive region, and the second surface of the thin film dielectric region coupled to the first surface of the second thin film conductive region; and
first, second, third, and fourth vias, each respectively having a first end and a second end, a first end of the first via coupled to the first end of the first thin film conductive region, a first end of the second via coupled to the second end of the first thin film conductive region, a first end of the third via coupled to the first end of the second thin film conductive region, and a first end of the fourth via coupled to the second end of the second thin film conductive region.

2. The device of claim 1, wherein the thin film dielectric region is a first thin film dielectric region, further comprising:
a second thin film dielectric region having a first surface and a second surface, the first surface of the second thin film dielectric region coupled to the second surface of the second thin film conductive region, the first end of the third via penetrating through the second thin film dielectric region to electrically couple to the first end of the second thin film conductive region, and the first end of the fourth via penetrating through the second thin film dielectric region to electrically couple to the second end of the second thin film conductive region.

3. The device of claim 1, wherein the thin film dielectric region provides an insulator between the first thin film conductive region and the second thin film conductive region.

4. The device of claim 1, wherein the first thin film conductive region and the second thin film conductive region are a silicon-carbon-chromium (SiCr) material, a nickel-chromium (NiCr) material, or a zero temperature coefficient conductive material.

5. The device of claim 1, wherein the thin film dielectric region is an oxide-nitride material.

6. The device of claim 1, further comprising first, second, third, and fourth metal lines, the first metal line coupled to the second end of the first via, the second metal line coupled to the second end of the second via, the third metal line coupled to the second end of the third via, and the fourth metal line coupled to the second end of the fourth via.

7. The device of claim 1, wherein the first and second thin film conductive regions and the thin film dielectric region are located in, or in contact with, a metal layer of a semiconductor device.

8. The device of claim 1,
wherein the first thin film conductive region, the first via, and the second via form a first resistor; and
wherein the second thin film conductive region, the third via, and the fourth via form a second resistor.

9. A device, comprising:
a semiconductor substrate having a substrate surface;
a first thin film conductive region having a first surface and a second surface;
a second thin film conductive region having a first surface and a second surface;
a third thin film conductive region having a first surface and a second surface, the third thin film conductive region electrically coupled to the second thin film conductive region;
a fourth thin film conductive region having a first surface and a second surface, the fourth thin film conductive region electrically coupled to the first thin film conductive region;
a first thin film dielectric region having a first surface and a second surface, the first surface of the first thin film dielectric region coupled to the first surface of the first thin film conductive region, and the second surface of the first thin film dielectric region coupled to the first surface of the second thin film conductive region; and
a second thin film dielectric region having a first surface and a second surface, the first surface of the second thin film dielectric region coupled to the first surface of the third thin film conductive region, and the second surface of the second thin film dielectric region coupled to the first surface of the fourth thin film conductive region;
wherein the first thin film conductive region is a same distance away from the substrate surface as the third thin film conductive region, and the second thin film conductive region is a same distance away from the substrate surface as the fourth thin film conductive region.

10. The device of claim 9,
wherein the first thin film conductive region has a same thickness as the third thin film conductive region; and
wherein the second thin film conductive region has a same thickness as the fourth thin film conductive region.

11. The device of claim 9, wherein each of the first, second, third, and fourth thin film conductive regions have respective first and second ends, further comprising:
first, second, third, and fourth vias, the first via electrically coupled to the first end of the first thin film conductive region, the second via electrically coupled to the first end of the second thin film conductive region, the third via electrically coupled to the first end of the third thin film conductive region and to the second via, and the fourth via electrically coupled to the first end of the fourth thin film conductive region and to the first via.

12. The device of claim 11, further comprising:
fifth, sixth, seventh, and eighth vias;
a first metal line coupled to the first via and the fifth via;
a second metal line coupled to the fifth via and the sixth via;
a third metal line coupled to the sixth via and the fourth via;
a fourth metal line coupled to the second via and the seventh via;
a fifth metal line coupled to the seventh via and the eighth via; and
a sixth metal line coupled to the eighth via and the third via.

13. The device of claim 11,
wherein the first thin film conductive region, the first via, the fourth via, and the fourth thin film conductive region correspond to a first resistor; and
wherein the second thin film conductive region, the second via, the third via, and the third thin film conductive region correspond to a second resistor.

14. The device of claim 9, further comprising first, second, third, fourth, fifth, sixth, seventh, and eighth vias, the first via electrically coupled to the first end of the first thin film conductive region, the second via electrically coupled to the second end of the first thin film conductive region, the third via electrically coupled to the first end of the second thin film conductive region, the fourth via electrically coupled to the second end of the second thin film conductive region, the fifth via electrically coupled to the first end of the third thin film conductive region, the sixth via electrically coupled to the second end of the third thin film conductive region, the seventh via electrically coupled to the first end of the fourth thin film conductive region, and the eighth via electrically coupled to the second end of the fourth thin film conductive region.

15. The device of claim 14, further comprising:
a third dielectric having a first surface and a second surface, the first surface of the third dielectric coupled to the second surface of the second thin film conductive region, and the third and fourth vias penetrating through the third dielectric to electrically couple to the second thin film conductive region; and
a fourth dielectric having a first surface and a second surface, the first surface of the fourth dielectric coupled to the second surface of the fourth thin film conductive region, and the seventh and eighth vias penetrating through the fourth dielectric to electrically couple to the fourth thin film conductive region.

16. A method of fabricating a semiconductor device, the method comprising:
depositing, patterning, and etching holes in a first inter-level oxide (ILO) layer;
depositing conductive material to fill holes etched in the first ILO layer to form a first via and a second via;
sequentially depositing a first thin film conductive layer, a first thin film dielectric layer, a second thin film conductive layer, and a second thin film dielectric layer;
patterning and etching the sequentially deposited layers to form a first thin film conductive region, a first thin film dielectric region, a second thin film conductive region, and a second thin film dielectric region;
depositing, patterning, and etching holes in a second ILO layer, so that holes are also etched in the second thin film dielectric region stopping at the second thin film conductive layer; and
depositing conductive material to fill holes etched in the second ILO layer and the second thin film dielectric region to form a third via and a fourth via.

17. The method of claim 16,
wherein the patterning and etching the sequentially deposited layers includes forming a third thin film conductive region, a third thin film dielectric region, a fourth thin film conductive region, and a fourth thin film dielectric region; and
wherein the third thin film conductive region, the third thin film dielectric region, the fourth thin film conductive region, and the fourth thin film dielectric region are horizontally displaced, with respect to a substrate surface of the semiconductor device, from the first thin film conductive region, the first thin film dielectric region, the second thin film conductive region, and the second thin film dielectric region.

18. The method of claim 16, wherein the patterning and etching the sequentially deposited layers includes:
forming the first thin film conductive region and the third thin film conductive region from the first thin film conductive layer; and
forming the second thin film conductive region and the fourth thin film conductive region from the second thin film conductive layer.

19. The method of claim 16,
wherein the patterning and etching the sequentially deposited layers includes forming a third thin film conductive region, a third thin film dielectric region, a fourth thin film conductive region, and a fourth thin film dielectric region; and
wherein the first thin film conductive region is electrically coupled to the fourth thin film conductive region to form a first resistor, and wherein the second thin film conductive region is electrically coupled to the third thin film conductive region to form a second resistor.

20. The method of claim 16,
wherein the first thin film conductive region, the first via, the fourth via, and the fourth thin film conductive region correspond to a first resistor; and
wherein the second thin film conductive region, the second via, the third via, and the third thin film conductive region correspond to a second resistor.
